(19) United States
(12) Patent Application Publication
(10) Pub. No.: US 2009/0309115 A1
(43) Pub. Date: Dec. 17, 2009

(54) SEMICONDUCTOR LIGHT EMITTING DEVICE

(75) Inventors: Masanori HOSHINO, Niiza-shi (JP); Takeshi SANO, Niiza-shi (JP); Toyomi YAMASHITA, Niiza-shi (JP); Nobuyuki SUZUKI, Niiza-shi (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: Sanken Electric Co., Ltd., Niiza-shi (JP)

(21) Appl. No.: 12/432,887

(22) Filed: Apr. 30, 2009

(30) Foreign Application Priority Data
Jun. 13, 2008 (JP) 2008-155822

(51) Int. Cl. H01L 33/00

(52) U.S. Cl. 257/98; 257/E33.059

(57) ABSTRACT

A semiconductor light emitting device includes: a package base having recesses which are open in a light irradiating direction; a plurality of light emitting elements arranged on bottoms of the recesses and emitting light having different colors; first light transmitting resin extending over the light emitting elements on the bottoms of the recesses and containing a fluorescent substance; and second light transmitting resin extending over the first transmitting resin in the recesses and oriented toward openings of the recesses, containing a fewer fluorescent substance than the fluorescent substance of the first light transmitting resin, and being thicker than the first light transmitting resin.

### CROSS REFERENCE TO RELATED APPLICATION

This application is based upon and claims the benefit of priority from the prior Japanese Patent Application No. 2008-155.822 filed on Jun. 13, 2008, the entire contents of which is incorporated herein by reference.

### BACKGROUND OF THE INVENTION

1. Field of the Invention

The present invention relates to a semiconductor light emitting device, and more particularly to a semiconductor light emitting device which is used as a light source for a back light of a liquid crystal display, a lighting fixture and so on.

2. Description of the Related Art

There is a trend toward using semiconductor light emitting devices, more particularly light emitting diodes (LED), as a light source for a back light, indoor illumination and so on. The light emitting diodes consume little electricity to work, have a long life, and do not contain any harmful substance such as mercury, i.e. cause little environmental impact.

White light is preferable for the back light and room illumination. Japanese Patent Laid-Open Publication No. 2000-275636 discloses a light source emitting white light and a lighting system. The light source and lighting system of the publication include blue light emitting diodes and red light emitting diodes which are alternately arranged, and are covered by fluorescent filters. White light is produced by mixing blue light from the blue light emitting diodes, green light which is obtained by wavelength conversion of blue light, and red light from the red light emitting diodes.

The foregoing light source and lighting system seem to have the following problem. The blue light, green light and red light are not sufficiently mixed. Especially, since the red light which is not absorbed by the fluorescent filter is emitted as it is, it is very difficult to obtain the white light which is optimum to the back light and room illumination.

This invention has been contemplated in order to overcome the foregoing problem, and provides a semiconductor light emitting device which can sufficiently mix light having different colors, can produce white light having excellent brightness and chroma saturation.

### SUMMARY OF THE INVENTION

According to a first feature of the embodiment of the invention, a semiconductor light emitting device includes a package base having recesses which are open in a light irradiating direction; a plurality of light emitting elements arranged on bottoms of the recesses and emitting light having different colors; first light transmitting resin extending over the light emitting elements on the bottoms of the recesses and containing a fluorescent substance; and second light transmitting resin extending over the first transmitting resin in the recesses and oriented toward an opening of the recess, containing a fewer fluorescent substance than the fluorescent substance of the first light transmitting resin, and being thicker than the first light transmitting resin.

In accordance with a second feature of the embodiment of the invention, a semiconductor light emitting device includes a package base having a first recess with a first opening oriented in a light irradiating direction, a second recess communicating with the first opening of the first recess, having a large opening compared to the first opening, and being deeper than the first recess; a plurality of light emitting elements arranged on a bottom of the recess and emitting light having different colors; first light transmitting resin filled in the first recess, extending over the light emitting elements and containing a fluorescent substance; and second light transmitting resin filled in the second recess, extending over the first transmitting resin, and containing a fewer fluorescent substance than the fluorescent substance of the first light transmitting resin, and being thicker than the first light transmitting resin.

With the second mentioned semiconductor light emitting device, a first inner surface of the first recess preferably has a first obtuse angle with respect to the first bottom of the first recess and reflects light emitted by the light emitting elements toward the light irradiating direction, and a second inner surface of the second recess preferably has a second inner angle with respect to a second bottom of the second recess. The second inner angle is smaller than the first inner angle. The second inner surface diffuses light from the light emitting elements in a direction crossing the light irradiating direction.

In the first or second mentioned semiconductor light emitting device the second light transmitting resin preferably contains a fluorescent substance.

Further, in the first or second mentioned semiconductor light emitting device, the light emitting elements are classified into blue light emitting elements, and red light emitting elements. The fluorescent substance absorbs blue light emitted by the blue light emitting elements and emits light having a wavelength different from a wavelength of the blue light. An absorption factor of the red light is smaller than an absorption factor of the blue light.

Still further, with the second mentioned semiconductor light emitting device, the package base preferably includes the first recess, a radiator with conductivity, and a resin body attached to the radiator, and having the second recess and light reflexivity.

The in invention provides the light emitting device which can promote color mixture of light from light emitting elements for generating different colors, and emit white light having excellent brightness and chroma saturation.

### BRIEF DESCRIPTION OF THE DRAWINGS

FIG. 1 is a cross sectional view of a semiconductor light emitting device according to one embodiment of the invention (taken along line F1-F1 in FIG. 2).

FIG. 2 is a top plan view of the semiconductor light emitting device shown in FIG. 1.

FIG. 3 is a perspective and partly cross sectional view of the semiconductor light emitting device shown in FIG. 1.

FIG. 4 is a simplified cross sectional view of a semiconductor light emitting device of the present invention used for experiments.

FIG. 5 is a cross sectional view of a semiconductor light emitting device of a comparison Example 1.

FIG. 6 is a cross sectional view of a semiconductor light emitting device of a comparison Example 2.

FIG. 7 is a cross sectional view of a semiconductor light emitting device of a comparison Example 3.

FIG. 8 is a graph showing relative chromaticity of the semiconductor light emitting device of the present invention, and light emitting devices of comparison Examples 1 to 3.

FIG. 9 is a graph showing chromaticity differences derived on the basis of the graph in FIG. 8.

### DETAILED DESCRIPTION OF THE INVENTION

The features and the advantages of the present invention will be more readily understood upon a thoughtful deliberation of the following detailed description of embodiments of the present invention with reference to the accompanying drawings. Like or corresponding parts are denoted by like or corresponding reference numerals. The drawings are schematic and may sometimes differ from actual components. Further, dimensions of components may be different in some drawings.

Any change and modification may still be confined to the following scope defined by the claims.

In an embodiment, the invention is applied to a semiconductor light emitting device used as a light source for a back light of a liquid crystal display, a household lighting fixture or the like.

### [Structure of Semiconductor Light Emitting Device]

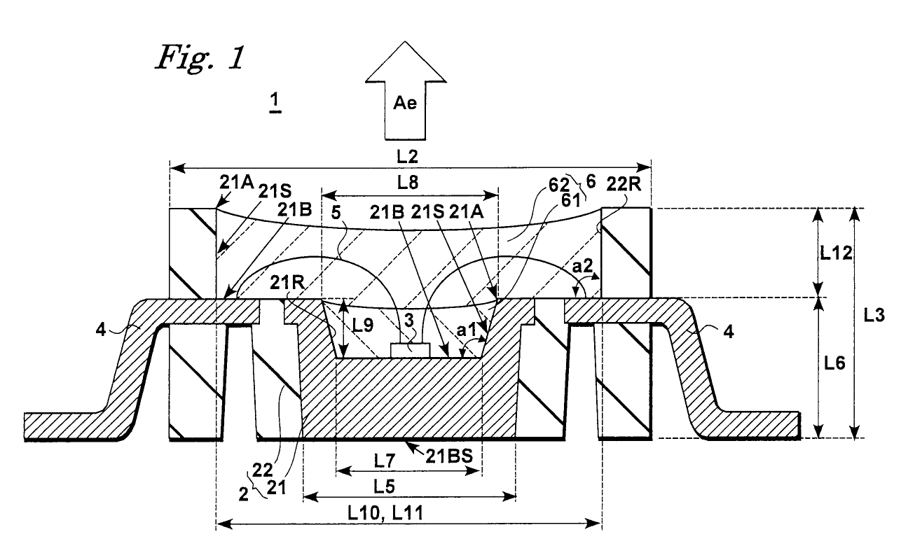

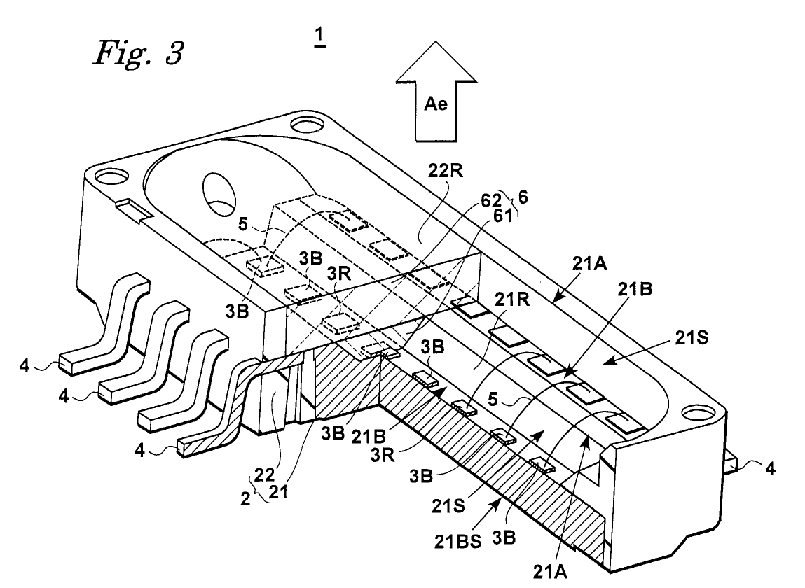

Referring to FIG. 1 to FIG. 3, a semiconductor light emitting device 1 includes a package base 2 having recesses (21R and 22R) which are open in a light irradiating direction Ae; a plurality of light emitting elements 3 which are positioned on a bottom of one recess (first recess 21R) and emit light having different colors; first light transmitting resin 61 extending over the light emitting elements 3 on the bottom of the first recess 21R and containing a fluorescent substance; and second light transmitting resin 62 which extends over the first light transmitting resin 61 in the other recess (second recess 22R), contains a small amount of the fluorescent substance compared to the first light transmitting resin 61, and is thicker than the first light transmitting resin 61.

The package base 2 includes a heat conduction radiator 21, and light reflecting resin 22 attached to the radiator 21. The radiator 21 has the first recess 21R. The light reflecting resin 22 has the second recess 22R.

The first recess 21R of the radiator 21 has an opening 21A oriented in the light irradiating direction Ae, has a first bottom 21B at a side opposite to the light irradiating direction Ae, and has a first inner surface 21S extending between the periphery of the first opening 21A and the first bottom 21B. In short, the first recess 21R serves as a storage space. The light irradiating direction Ae is perpendicular to the first bottom 21B and extends to the first recess 21R from the first bottom 21B.

The radiator 21 not only serves as a base substrate for the package base 2 but also radiates heat which is produced in response to the light emitting operation of the light emitting elements 3 mounted on the first bottom 21B. The first inner surface 21S of the first recess 21R functions as a reflector which reflects light generated by the light emitting elements 3, e.g. light mainly generated on the first bottom 21B, toward the irradiating direction Ae. In this embodiment, the radiator 21 is made of a copper (Cu) alloy sheet metal which has excellent heat conductivity, and has its surface plated using Ag, Pd or Rh. For instance, the package base 2 has a length L1 of 13.2 mm to 13.4 mm, a width L2 of 5.2 mm to 5.4 mm, and a depth L3 of 2.4 mm to 2.6 mm. The radiator 12 has a length L4 of 11.3 mm to 11.5 mm, a width L5 of 4.2 mm to 4.4 mm, and a depth of 1.4 mm to 1.6 mm. Further, the first bottom 21B of the first recess 21R has a width L7 of 0.6 mm to 1.0 mm, and the first opening 21A has a width L8 of 1.4 mm to 1.8 mm, and the first recess 21R has a depth L9 of 0.3 mm to 1.0 mm. The sizes of the foregoing components may have difference values.

The resin 22 is insert-molded into the radiator 21. A rear surface 21BS of the radiator 21, which is opposite to the first recess 21R, is exposed, is molded around the radiator 21, and is thickened toward the light irradiating direction Ae. The second recess 22R of the resin 22 has an opening 22A facing to the irradiating direction Ae, and has a second bottom 22B at a side opposite to the irradiating direction Ae. A second inner surface 22S is present around the second opening 22A and the second bottom 22B. In short, the second recess 22R serves as a storage space, and is in the shape of an inverted trapezoid. The second bottom 22B of the second recess 22R communicates with the first opening 21A of the first recess 21R. The second bottom 22B and second opening 22A of the second recess 22R are larger than the first bottom 21B and first opening 21A of the first recess 21R.

The resin 22 defines a profile of the package base 2, and functions as a dam for filling light transmitting resin 62. The second inner surface 22S of the second recess 22R functions as a reflector, which reflects light from the light emitting elements 3 in a direction crossing the light irradiating direction Ae, and diffuses and mixes light having different colors. In this embodiment, the resin 22 is preferably nylon group resin, especially polyamide resin, which is called “white resin” and has excellent reflectivity.

The second bottom 22B of the second recess 22R has a width L10 of 3.9 mm to 4.3 mm, for instance. The second opening 22A has a width L11 of 4.2 mm to 4.4 mm. The second recess 22R has a depth L12 of 0.9 mm to 1.1 mm. The depth L12 of the second recess 22R is larger than the depth L9 of the first recess 21R. In other words, the second light transmitting resin 62 is thicker than the first light transmitting resin 61, i.e. the second light transmitting resin 62 has an optical path extending in the light irradiating direction which is longer than an optical path of the first light transmitting resin 61.

In the radiator 21, a first inner angle a1 of the first inner surface 21S (reflecting surface) of the recess 21R with respect to the bottom 21B is designed to be between an obtuse angle a1 of 90 degrees or larger and less than 180 degrees, which enables the inner surface 21S to function as the reflecting surface. In this embodiment, the first inner angle is designed to be 130 degrees to 150 degrees, for instance. In the resin 22, a second inner angle a2 of the second inner surface 22S (light diffusing surface) of the second recess 22R with respect to the second bottom 22B is designed to be smaller than the first inner angle a1 or an obtuse angle, which enables the second inner surface 22B to function as the light reflecting surface. The inner angle a2 is designed to be 90 degrees to 110 degrees, for instance.

The light emitting elements 3 are constituted by blue light emitting diodes 3B, and red light emitting diodes 3R. The blue light emitting diodes 3B emit blue light having a wavelength of approximately 450 nm to 490 nm, and are semiconductor chips which are made by depositing an InGaN group semiconductor on a sapphire substrate or a silicon substrate. The red light emitting diodes 3R emit red light having a wavelength of approximately 620 nm to 780 nm, and are semiconductor chips which are made by depositing an AlGaInP group semiconductor on an AlN substrate or a sapphire substrate.

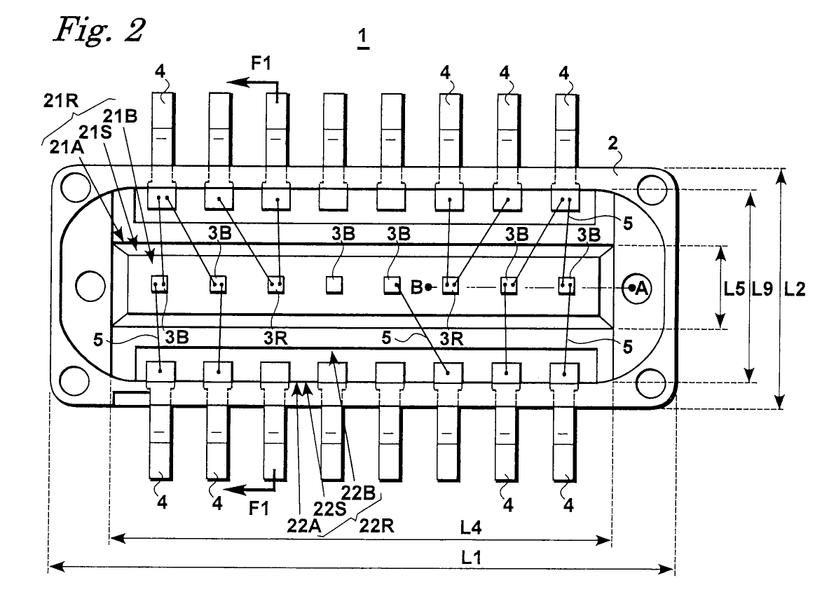

Each of the semiconductor chips is a square or rectangle having four straight sides, each of which is 0.3 mm to 0.4 mm long. Referring to FIG. 2, the blue light emitting diodes 3B and red light emitting diodes 3R are mounted on the first bottom 21B of the first recess 21R of the radiator 21 with an array pitch of 1.2 mm to 1.3 mm, and are lined up sideways in a longitudinal direction. From left to right shown in FIG. 2, there are arranged two blue light emitting diodes 3B, one red light emitting diode 3R, two blue light emitting diodes 3B, one red light emitting diode 3R and two blue light emitting diodes 3B. A total of eight light emitting diodes, i.e. six blue light emitting diodes 3B and two red light emitting diodes 3R, are arranged in a row. The arrangement pattern of the light emitting diodes is not always limited to the foregoing pattern. In this embodiment, every two blue light emitting diodes 3B and one red light emitting diode 3R are repeatedly arranged as a group. Alternatively, the semiconductor light emitting device 1 may include any number of light emitting diodes.

The first light transmitting resin 61 filled in the first recess 21R extends over the light emitting elements 3, protects them against the external environment, and includes a fluorescent substance (not shown) which mainly absorbs a part of blue light emitted by the blue light emitting diodes 3B and converts blue light to another light having a different wavelength. The first light transmitting resin 61 is made by potting resin in the first recess 21R, and is then cured. In this case, the first light transmitting resin 21 is filled using the surface tension until it reaches the peripheral edge of the opening 21A of the first recess 21R.

In this embodiment, the first light transmitting resin 61 is silicon resin, for instance. The fluorescent substance added to the silicon resin is a silicate group fluorescent substance which can absorb a part of blue light, and emit yellow light, or complementary color light, having a wavelength of approximately 580 nm to 600 nm. The fluorescent substance is preferably contained in the first light transmitting resin 61 in an amount of 5 weight percent to 40 weight percent. Alternatively, the fluorescent substance may be a YAG or TAG group fluorescent substance. The term “complementary color” denotes a color which is changed to white when it is mixed with a single light color or a plurality of light colors.

The light transmitting resin 62 filled in the second recess 22R diffuses and mixes not only the blue light emitted by the blue light emitting diodes 3B and the red light emitted by the red light emitting diodes 3R but also the yellow light which is obtained by converting a part of the blue light using the first light transmitting resin 61. The second light transmitting resin 62 may contain the fluorescent substance of the first light transmitting resin 61. The fluorescent substance of the first light transmitting resin 61 may be contained in the second light transmitting resin 62 in an amount which is smaller than that of the first light transmitting resin 61. In this embodiment, no fluorescent substance is present in the second light transmitting resin 62. The second light transmitting resin 62 includes a light diffusing material in order to promote diffusion and mixing of light. The light diffusing material is preferably a silicon dioxide filler, which is in a ratio of 3 weight percent to 10 weight percent.

The second light transmitting resin 62 is also filled by the potting process, and is then cured. In this embodiment, the second light transmitting resin 62 is filled up to the peripheral edge of the second opening 22A using the surface tension.

The resin 22 of the package body 2 has its one end (an inner lead) positioned on the second bottom 22B of the second recess 22R. Leads 4 which are molded and stick out on the outer surface of the resin 22 are connected to the other end (an outer end) of the resin 22. One end each of the leads 4 is electrically connected to anode (or cathode) electrodes (not shown) of the light emitting elements 3 using a wire 5. In this embodiment, the other ends of the leads 4 are molded in the shape of a gull wing.

The leads 4 are made of a Cu alloy sheet, and are Ag-plated at some of their opposite ends. The wire 5 may be an Au, Pd or Rh wire, and is electrically and mechanically connected to the anode or cathode electrodes of the light emitting elements 3 using the ultrasonic bonding technology.

### [Light Emitting Operation of Light Emitting Device]

The semiconductor light emitting device 1 emits light as described hereinafter. Electric power is supplied to the anode and cathode electrodes of the light emitting elements 3 via the leads 4 and the wire 5. In this state, the blue light emitting diodes 3B start to emit blue light while the red light emitting diodes 3R start to emit red light.

The blue light from the blue light emitting diodes 3B is directly irradiated in the light irradiating direction Ae in the first light transmitting resin 61 of the first recess 21R, is reflected by the inner surface 21S of the first recess 21, and is then irradiated in the light irradiating direction Ae. The red light from the red light emitting diodes 3R is directly irradiated in the light irradiating direction Ae in the first light transmitting resin 61 of the first recess 21R, is reflected by the inner surface 21S of the first recess 21, and is then irradiated in the light irradiating direction Ae. A part of the blue light emitted by the blue light emitting diodes 3B is absorbed by the fluorescent substance, from which complementary yellow light is emitted. The blue light, red light and yellow light are mixed in the first light transmitting resin 61 in order to generate white light. The white light is radiated to the second light transmitting resin 62 of the second recess 22R.

The second light transmitting resin 62 contains the light diffusing substance. The second angle a2 of the second inner surface 22S of the second recess 22 with respect to the second bottom 22B is smaller than the first inner angle a1 of the first inner surface 21S of the first recess 21. Therefore, the white light is extensively diffused and mixed in the direction crossing the light irradiating direction Ae. Further, since the second light transmitting resin 62 is thicker than the first light transmitting resin 61, the white light is diffused and mixed for a longer time period. In other words, the blue light, red light and yellow light are mixed until such mixing does not cause a practical issue. Then, the mixed color light is radiated in the light irradiating direction Ae. The semiconductor light emitting device 1 of this embodiment can emit the white light which is substantially free from the blue or red light.

### [Experiments]

Light mixing property of the semiconductor light emitting device 1 has been demonstrated based on experiments conducted by the inventors.

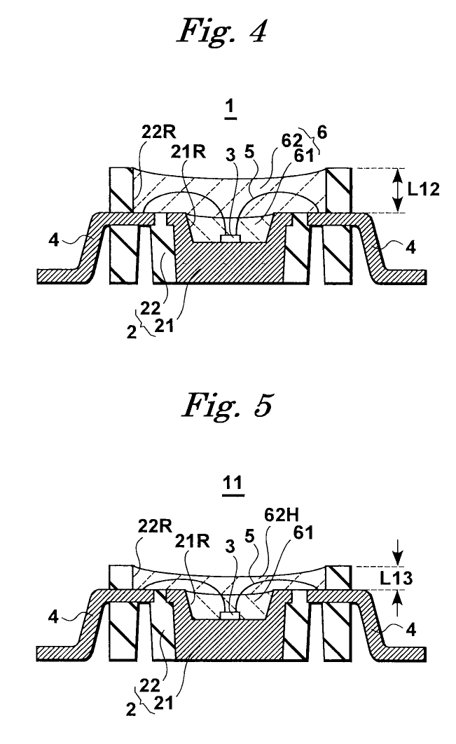

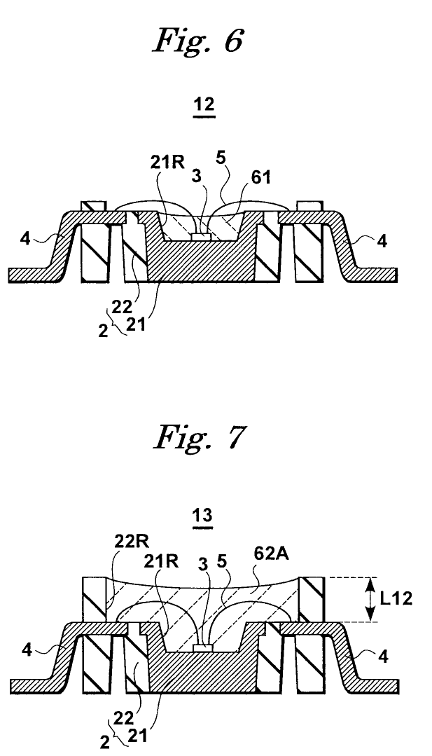

FIG. 4 to FIG. 7 show samples used for the experiments. FIG. 4 is the cross sectional view of the semiconductor light emitting device 1 of the present invention used for experiments. The semiconductor light emitting device 1 includes the first light transmitting resin 61 filled in the first recess 21, and the second light transmitting resin 62 filled in the second recess 22R.

FIG. 5 to FIG. 7 show semiconductor light emitting devices 11 to 13 of Comparison Examples 1 to 3. A semiconductor light emitting device 11 (Comparison Example 1) shown in FIG. 5 is fundamentally similar to the semiconductor light emitting device 1. A depth L13 of a second recess 22R of the semiconductor light emitting device 11 is a half of the depth L12 of the second recess 22R of the semiconductor light emitting device 1. Further, a depth of a light transmitting resin 62 of the Comparison Example 1 is a half of the depth of the second light transmitting resin 62 of the present invention.

A semiconductor light emitting device 12 (Comparison Example 2) includes only the first light transmitting resin 61 filled in the recess 21, but does not include the second recess 22R and second light transmitting resin 62. Referring to FIG. 7, a semiconductor light transmitting device 13 (Comparison Example 3) has the first and second recesses 21R and 22R. However, only light transmitting resin 62A, which corresponds to the second light transmitting resin 62, is filled in the first and second recesses 21R and 22R.

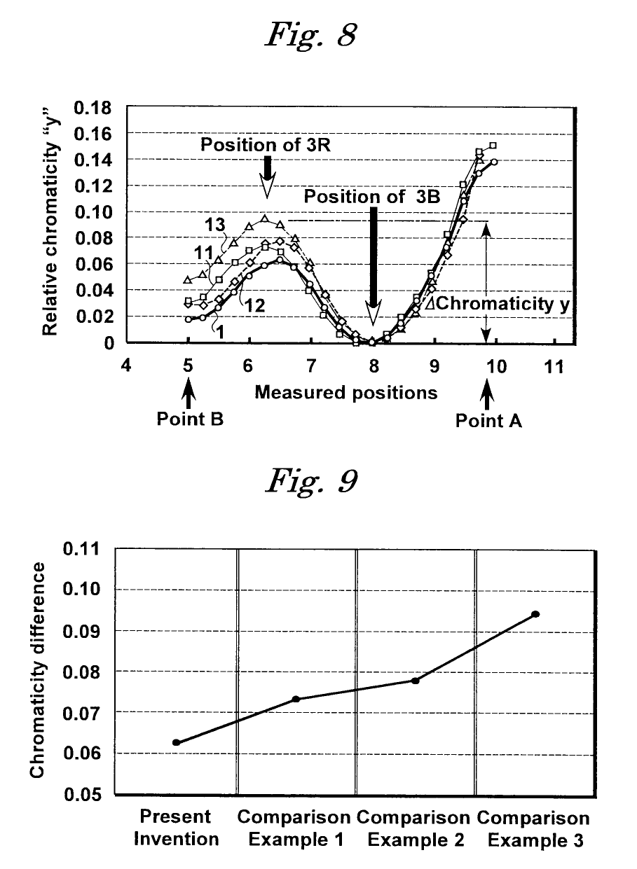

FIG. 8 is the graph showing relative chromaticity of the semiconductor light emitting device 1 of the present invention, and the semiconductor light emitting devices of Comparison Examples 1 to 3. The abscissa denotes positions where the chromaticity is measured between a point A and a point B at the right and left sides of the package body 2. The ordinate denotes relative chromaticity y when the chromaticity on the blue light emitting diodes 3B is assumed to be zero. FIG. 9 is a graph showing the relationship between chromaticity differences and positions of the blue light emitting diodes 3B and the red light emitting diodes 3R. In FIG. 9, the abscissa denotes the semiconductor light emitting device 1 of the present invention, and the semiconductor light emitting devices 11 to 13 of the Comparison Examples 1 to 3 while the ordinate denotes the chromaticity differences.

When modifying the graph of FIG. 8 in such a manner that the chromaticity is zero at the point A where the blue light emitting diodes 3B are positioned, there are chromaticity differences at the point B where the red light emitting diodes 3R are positioned, in the light emitting device of the present invention and the light emitting devices 11 to 13 of the Comparison Examples 1 to 3. Referring to FIG. 9, the chromaticity difference at the positions of the blue light emitting diodes 3B and red light emitting diodes 3R is approximately 0.062 to 0.063, and is minimum in the semiconductor light emitting device 1 of the present invention.

A chromaticity difference of the semiconductor light emitting device 11 (Comparison Example 1) is slightly large, i.e. approximately 0.073 to 0.074. This is because the second recess 22R is shallow, and because the second light transmitting resin 62 is thin. The semiconductor light emitting device 12 of the Comparison Example 2 has neither the second recess 22R nor the second light transmitting resin 62, so that a chromaticity difference thereof becomes extensively large, i.e. approximately 0.077 to 0.078. This is because neither diffusion nor color mixture is promoted. In the Comparison Example 3, the semiconductor light emitting device 13 is free from color mixture, and has a maximum chromaticity difference of approximately 0.094 to 0.095 since no complimentary yellow light is produced by the first light transmitting resin 61 filled in the first recess 21R.

As described so far, the semiconductor light emitting device 1 includes the first light transmitting resin 61 and the second light transmitting resin 62. The first light transmitting resin 61 contains the florescent substance which promotes the color mixture of light having different colors generated by the light emitting elements 3. The second light transmitting resin 62 contains the diffusing agent, and extensively promotes the color mixture. Therefore, the semiconductor light emitting device 1 can emit the white light having high brightness and chroma saturation.

Further, in the semiconductor light emitting device 1, the second inner surface 22S of the second recess 22R is very steep compared to the first inner surface 21S of the first recess 21R, which is effective in promoting the light diffusion and color mixture.

Still further, with the semiconductor light emitting device 1, the second recess 22R is deeper than the first recess 21R, and the second light transmitting resin 62 is thicker than the first light transmitting resin 6. This is effective in extensively promoting the diffusion and mixing of colored light in the second light transmitting resin 61.

### Other Embodiments

While the invention has been described with reference to the specific embodiment, numerous modification and variations could be made thereto without departing the scope of the invention set forth in the claims. For instance, the semiconductor light emitting device 1 includes the eight light emitting elements 3 which are arranged sideways in a row. Alternatively, more than eight light emitting elements 3 may be provided in the semiconductor light emitting device 1.

The present invention is not always limited to the blue and red light emitting diodes 3B and 3R. For instance, the invention is also applicable a light emitting device which includes blue and red light emitting diodes 3B and 3R and green light emitting diodes.

Further, the invention is applicable to a light emitting device which has a third recess communicating with the second recess 22R. The third recess is filled with light transmitting resin which promotes light diffusion and color mixture.

What is claimed is:

1. A semiconductor light emitting device comprising:
a package base having recesses which are open in a light irradiating direction;
a plurality of light emitting elements arranged on bottoms of the recesses and emitting light having different colors;
first light transmitting resin extending over the light emitting elements on the bottoms of the recesses and containing a fluorescent substance; and
second light transmitting resin extending over the first transmitting resin in the recesses and oriented toward the openings of the recesses, containing a fewer fluorescent substance than the fluorescent substance of the first light transmitting resin, and being thicker than the first light transmitting resin.

2. A semiconductor light emitting device comprising:
a package base having a first recess with a first opening oriented in a light irradiating direction, and a second recess communicating with the first opening of the first recess, having a large opening compared to the first opening, and being deeper than the first recess;
a plurality of light emitting elements arranged on a bottom of the first recess and emitting light having different colors;
first light transmitting resin filled in the first recess, extending over the light emitting elements and containing a fluorescent substance; and
second light transmitting resin filled in the second recess, extending over the first transmitting resin, and containing a fewer fluorescent substance than the fluorescent substance of the first light transmitting resin, and being thicker than the first light transmitting resin.

3. The semiconductor light emitting device defined in claim 2, wherein a first inner surface of the first recess has a first obtuse angle with respect to the first bottom of the first recess and reflects light emitted by the light emitting elements in the light irradiating direction; and a second inner surface of the second recess has a second inner angle with respect to a second bottom of the second recess, the second inner angle being smaller than the first inner angle, and the second inner surface diffusing light from the light emitting elements in a direction crossing with the light irradiating direction.

4. The semiconductor light emitting device defined in claim 1, wherein the second light transmitting resin contains a fluorescent substance.

5. The semiconductor light emitting device defined in claim 2, wherein the second light transmitting resin contains a fluorescent substance.

6. The semiconductor light emitting device defined in claim 1, wherein the light emitting elements are classified into elements emitting blue light, and elements emitting red light; the fluorescent substance absorbs light emitted by the blue light emitting elements and emits light having a wavelength different from a wavelength of the light before it is absorbed; and an absorption factor of the red light is smaller than an absorption factor of the blue light.

7. The semiconductor light emitting device defined in claim 2, wherein the light emitting elements are classified into elements emitting blue light, and elements emitting red light; the fluorescent substance absorbs light emitted by the blue light emitting elements and emits light having a wavelength different from a wavelength of the light before it is absorbed; and an absorption factor of the red light is smaller than an absorption factor of the blue light.

8. The semiconductor light emitting device defined in claim 2, wherein the package base includes the first recess, a radiator with thermal conductivity, and resin attached to the radiator, and having the second recess and light reflexivity.

9. The semiconductor light emitting device defined in claim 3, wherein the package base includes the first recess, a radiator with thermal conductivity, and resin attached to the radiator, and having the second recess and light reflexivity.

10. The semiconductor light emitting device defined in claims 6, wherein the package base includes the first recess, a radiator with thermal conductivity, and resin attached to the radiator, and having the second recess and light reflexivity.
